(19) United States
(12) Patent Application Publication
(10) Pub. No.: US 2017/0125240 A1
(43) Pub. Date: May 4, 2017

(54) METHOD FOR MANUFACTURING SEMICONDUCTOR AND METHOD FOR CLEANING WAFER SUBSTRATE

(71) Applicants: National Institute of Advanced Industrial Science and Technology, Tokyo (JP); OPT Creation Inc., Yokohama-shi, Kanagawa (JP)

(72) Inventors: Masayoshi TAKAHASHI, Tsukuba-shi (JP); Tsunejiro TAKAHASHI, Yokohama-shi (JP); Katsumi TATERA, Yokohama-shi (JP); Junichi IIDA, Yokohama-shi (JP)

(73) Assignees: National Institute of Advanced Industrial Science and Technology, Tokyo (JP); OPT Creation Inc., Yokohama-shi, Kanagawa (JP)

(21) Appl. No.: 15/300,432

(22) PCT Filed: Mar. 31, 2015
(86) PCT No.: PCT/JP2015/060088

§ 371 Date: Sep. 29, 2016

(30) Foreign Application Priority Data
Mar. 31, 2014 (JP) 2014-073368

(51) Int. Cl. H01L 21/02; B08B 3/08; G03F 7/36; B08B 1/04; B08B 1/00; H01L 21/3105; B08B 3/10

(52) U.S. Cl. CPC H01L 21/02057; H01L 21/31058; B08B 3/08; B08B 3/10; B08B 1/04; B08B 1/002; G03F 7/36

(57) ABSTRACT

An object of the present invention is to provide a method for manufacturing a semiconductor, including a step of removing a photoresist present on a patterned wafer substrate and having a hardened modified layer, which is difficult to remove, formed on at least part of a top portion easily and effectively under mild conditions, and a method for cleaning a wafer substrate, including the above step. The method for manufacturing a semiconductor of the present invention as a means for resolution is characterized by comprising a step of bringing a patterned wafer substrate, on which a photoresist having a hardened modified layer formed on at least part of a top portion is present, into contact with a carbon dioxide dissolved water containing ozone-containing microbubbles, thereby removing the photoresist. In addition, the method for cleaning a wafer substrate of the present invention is characterized by comprising the above step.

### TECHNICAL FIELD

The present invention relates to a method for manufacturing a semiconductor, including a step of removing a photoresist, which has been used to form a circuit pattern on a wafer substrate, easily and effectively under mild conditions. The present invention also relates to a method for cleaning a wafer substrate, including the above step.

### BACKGROUND ART

The semiconductor manufacturing process includes a circuit design step, a mask manufacturing step, a wafer manufacturing step, a wafer processing step, an assembly step, an inspection step, a waste processing step, and the like. Among them, a wafer processing step for fabricating a predetermined circuit pattern on a wafer substrate is a core of the semiconductor manufacturing process.

The formation of a circuit pattern on a wafer substrate is performed through a step of forming an oxide film or a polysilicon film on the surface of a wafer substrate, a step of applying a photoresist to the surface of the film, a step of transferring the circuit pattern of a photomask onto the photoresist by exposure, a step of forming a resist pattern by development, a step of etching to remove the oxide film or polysilicon film according to the resist pattern, a step of removing the unnecessary photoresist, and the like. As a result of repeating the series of steps, a predetermined circuit pattern is fabricated on the wafer substrate.

In the course of fabricating a predetermined circuit pattern on a wafer substrate, the patterned wafer substrate is subjected to a treatment such as ion implantation or plasma irradiation. In the case where such a treatment is performed while a photoresist is present on the wafer substrate, the photoresist is affected by the treatment, and the organic material forming the photoresist is deteriorated, resulting in the formation of a hardened modified layer, which is difficult to remove, on at least part of a top portion of the photoresist. In particular, when the photoresist is affected by high-dose ion implantation, a crust composed of an amorphous carbonized layer is formed, which is extremely difficult to remove. In addition, also in the case of a photoresist affected by dry etching of an oxide film or a polysilicon film using a chlorine-based or fluorine-based gas, for example, a hardened modified layer which is difficult to remove is formed on at least part of a top portion of the photoresist.

Methods for effectively removing a photoresist having a hardened modified layer, which is difficult to remove, formed on at least part of a top portion have been proposed. For example, Patent Document 1 proposes a composition for removing a high-dose ion-implanted photoresist from the surface of a semiconductor device, containing at least one solvent having a flash point of more than 65° C. (e.g., sulfolane), at least one component that provides nitronium ions (e.g., nitronium tetrafluoroborate), and at least one phosphonic acid corrosion inhibitor compound (e.g., amino trimethylene phosphonic acid). In addition, in light of the fact that a crust is extremely insoluble in an aqueous cleaner, particularly in a cleaner that does not impair dielectricity, and that the removal thereof requires the addition of considerable amounts of auxiliary solvent, humectant, and/or surfactant to an aqueous solution to improve the cleaning efficiency of the solution, Patent Document 2 proposes a dense fluid concentrate useful for removing a hardened photoresist from a microelectronic element, containing at least one auxiliary solvent, optionally at least one oxidizing agent/radical supply source, optionally at least one surfactant, and optionally at least one silicon-containing layer deactivator. The dense fluid concentrate is characterized by further containing at least one of the following components (I) and (II) : (I) at least one fluoride supply source and optionally at least one acid, and (II) at least one acid. In addition, Patent Document 3 proposes a method for removing an ion-implanted photoresist material from a semiconductor structure, the method including: a step of providing a patterned photoresist on the surface of a semiconductor structure, wherein the patterned photoresist has at least one opening that exposes the upper surface of a semiconductor substrate of the semiconductor structure; a step of introducing a dopant by ion implantation into the exposed upper surface of the semiconductor substrate and the patterned photoresist; a step of forming a polymer film containing an oxidizing agent on at least the exposed upper surface of the ion-implanted and patterned photoresist; a step of performing a baking step for causing a reaction between the polymer film and the ion-implanted and patterned photoresist to form a modified patterned photoresist that dissolves in an aqueous, acidic, or organic solvent; and a step of removing the modified patterned photoresist from the semiconductor structure using an aqueous, acidic, or organic solvent.

The proposals in Patent Documents 1 to 3 are noteworthy as methods for effectively removing a photoresist having a hardened modified layer, which is difficult to remove, formed on at least part of a top portion. However, the composition described in Patent Document 1 contains an organic solvent, and thus care must be taken for waste liquid disposal. In addition, in order to remove the photoresist, a high temperature near 100° C. or a higher temperature is required, and thus care must also be taken in terms of equipment and safety. The dense fluid concentrate described in Patent Document 2 contains an acid, and thus care must be taken for waste liquid disposal. In addition, in order to remove the photoresist, a supercritical or near-supercritical environment has to be created at a high pressure of 100 atm or more, and thus care must also be taken in terms of equipment and safety. According to the method described in Patent Document 3, the removal of the photoresist requires a multistep process. In addition, because a high temperature near 100° C. is required, care must be taken in terms of equipment and safety. In view of these points, it is preferable that the removal method is a method that can be performed easily and effectively under mild conditions even when the object to be removed is a photoresist having a hardened modified layer, which is difficult to remove, formed on at least part of a top portion.

### PRIOR ART DOCUMENTS

### Patent Document

Patent Document 1: JP-A-2012-518716

Patent Document 2: JP-A-2008-547050

Patent Document 3: JP-A-2013-508961

### SUMMARY OF THE INVENTION

### Problems that the Invention is to Solve

Thus, an object of the present invention is to provide a method for manufacturing a semiconductor, including a step of removing a photoresist present on a patterned wafer substrate and having a hardened modified layer, which is difficult to remove, formed on at least part of a top portion easily and effectively under mild conditions, and a method for cleaning a wafer substrate, including the above step.

### Means for Solving the Problems

Takahashi, who is one of the present inventors, has intensively studied water containing ozone-containing microbubbles. As a result of study, Takahashi has proposed, in WO 2009/099138, a method for cleaning a semiconductor wafer using water containing ozone-containing microbubbles, which can be performed easily and effectively under mild conditions. According to the method proposed by Takahashi in WO 2009/099138, water containing ozone-containing microbubbles is brought into contact with the surface of a semiconductor wafer. As a result, at or in the vicinity of the interfaces with the object to be removed, including an organic substance such as a photoresist, microbubbles, which rapidly decrease in size and disappear upon physical or chemical stimulation, release hydroxyl ions or the like concentrated at the gas-liquid interfaces into the surrounding space during the collapsing process of microbubbles. At this time, accumulated energy is also released. Accordingly, ozone molecules present inside or around the bubbles are decomposed, whereby active species including at least hydroxyl radicals are generated. Such active species generated powerfully decompose or solubilize the object to be removed, and also promote the separation of the object to be removed from the surface of the semiconductor wafer. As a result, an excellent cleaning effect is exerted. However, as a result of research by the present inventors, it has turned out that when a photoresist is affected by ion implantation of phosphorus or the like at a high dose of more than 5×10¹⁴ ions/cm², or when a photoresist is affected by dry etching of an oxide film or a polysilicon film using a chlorine-based or fluorine-based gas for more than 1 minute, for example, the top portion of such a photoresist is significantly hardened and modified, and therefore, according to the method described in WO 2009/099138, the removal takes a long period of time. In order to reduce the time taken to remove such a photoresist, it is effective to previously perform ashing using an oxygen plasma or the like. However, ashing may adversely affect the formed circuit pattern. Thus, the present inventors have improved the method described in WO 2009/099138, and conducted extensive research to achieve a method, according to which even a photoresist having a hardened modified layer, which is difficult to remove, formed on at least part of a top portion can be removed within a short period of time in a wet process. As a result, they have found that the time taken to remove such a photoresist can be reduced by dissolving carbon dioxide in water containing ozone-containing microbubbles.

A method for manufacturing a semiconductor of the present invention accomplished based on the above findings is, as defined in claim 1, characterized by comprising a step of bringing a patterned wafer substrate, on which a photoresist having a hardened modified layer formed on at least part of a top portion is present, into contact with a carbon dioxide dissolved water containing ozone-containing microbubbles, thereby removing the photoresist.

A method for manufacturing a semiconductor as defined in claim 2 is characterized in that in the method for manufacturing a semiconductor according to claim 1, the microbubbles have a particle size of 50 μm or less, the particle size has a peak at 10 to 15 μm as measured with a laser-light-blocking liquid particle counter, and the number of microbubbles in the peak region is 1000/mL or more.

A method for manufacturing a semiconductor as defined in claim 3 is characterized in that in the method for manufacturing a semiconductor according to claim 1, the carbon dioxide dissolved water containing ozone-containing microbubbles is prepared by generating ozone-containing microbubbles in water containing dissolved carbon dioxide.

A method for manufacturing a semiconductor as defined in claim 4 is characterized in that in the method for manufacturing a semiconductor according to claim 1, the carbon dioxide dissolved water containing ozone-containing microbubbles has a carbon dioxide concentration of 0.05 to 30 ppm.

A method for manufacturing a semiconductor as defined in claim 5 is characterized in that in the method for manufacturing a semiconductor according to claim 1, the carbon dioxide dissolved water containing ozone-containing microbubbles has a pH of 4.5 to 6.0.

A method for manufacturing a semiconductor as defined in claim 6 is characterized in that in the method for manufacturing a semiconductor according to claim 1, the step of removing the photoresist is performed with heating.

A method for manufacturing a semiconductor as defined in claim 7 is characterized in that in the method for manufacturing a semiconductor according to claim 6, the heating is performed to 30 to 80° C.

A method for manufacturing a semiconductor as defined in claim 8 is characterized in that in the method for manufacturing a semiconductor according to claim 1, before and/or with the step of removing the photoresist, the patterned wafer substrate, on which a photoresist having a hardened modified layer formed on at least part of a top portion is present, is subjected to at least one treatment selected from a treatment of roughening a surface of the hardened modified layer and a treatment of forming a scratch and/or a crack on a surface of the hardened modified layer.

A method for cleaning a wafer substrate of the present invention is, as defined in claim 9, characterized by comprising a step of bringing a patterned wafer substrate, on which a photoresist having a hardened modified layer formed on at least part of a top portion is present, into contact with a carbon dioxide dissolved water containing ozone-containing microbubbles, thereby removing the photoresist.

### Effect of the Invention

The present invention makes it possible to provide a method for manufacturing a semiconductor, including a step of removing a photoresist present on a patterned wafer substrate and having a hardened modified layer, which is difficult to remove, formed on at least part of a top portion easily and effectively under mild conditions, and a method for cleaning a wafer substrate, including the above step.

### BRIEF DESCRIPTION OF THE DRAWINGS

FIG. 1 A graph showing the relation between the pH of water containing microbubbles and the zeta potential of the microbubbles.

FIG. 2 A schematic diagram showing that because of the large overlap between the diffusion layer that accompanies an ozone-containing microbubble contained in water and the diffusion layer that accompanies a photoresist, repulsion between the two is strong, making it difficult for ozone-containing microbubbles to enter the grooves and holes of a pattern.

FIG. 3 A schematic diagram showing that because of the small overlap between the diffusion layer that accompanies an ozone-containing microbubble contained in water and the diffusion layer that accompanies a photoresist, repulsion between the two is weak, making it easy for ozone-containing microbubbles to enter the grooves and holes of a pattern.

FIG. 4 In Example 1, a microphotograph of a wafer substrate before pouring a carbon dioxide dissolved water containing ozone microbubbles.

FIG. 5 Similarly, a microphotograph of the same portion after 3 minutes from the start of the pouring of the carbon dioxide dissolved water containing ozone microbubbles.

FIG. 6 Similarly, a microphotograph of the same portion after 5 minutes from the start of the pouring of the carbon dioxide dissolved water containing ozone microbubbles.

FIG. 7 Similarly, a microphotograph of a different portion after 2 minutes from the start of the pouring of the carbon dioxide dissolved water containing ozone microbubbles.

FIG. 8 In Example 5, a microphotograph of a wafer substrate before pouring a carbon dioxide dissolved water containing ozone microbubbles.

FIG. 9 Similarly, a microphotograph of the same portion after 3 minutes from the start of the pouring of the carbon dioxide dissolved water containing ozone microbubbles.

FIG. 10 In Reference Example 1, a graph showing time-dependent changes in the thickness of a flexible photoresist after the start of the pouring of a carbon dioxide dissolved water containing ozone microbubbles.

### MODE FOR CARRYING OUT THE INVENTION

The method for manufacturing a semiconductor of the present invention is characterized by comprising a step of bringing a patterned wafer substrate, on which a photoresist having a hardened modified layer formed on at least part of a top portion is present, into contact with a carbon dioxide dissolved water containing ozone-containing microbubbles, thereby removing the photoresist.

In the present invention, the object to be removed by a carbon dioxide dissolved water containing ozone-containing microbubbles is a photoresist that is present on a patterned wafer substrate and has a hardened modified layer, which is difficult to remove, formed on at least part of a top portion. The hardened modified layer, which is difficult to remove, formed on at least part of a top portion of the photoresist is a layer that has been hardened as a result of the deterioration of the organic material forming the photoresist. Specifically, in the course of fabricating a predetermined circuit pattern on a wafer substrate, when the patterned wafer substrate is subjected to a treatment such as ion implantation or plasma irradiation, a photoresist is present on the wafer substrate and thus is affected by the treatment, resulting in the formation of such a hardened modified layer. In particular, a crust composed of an amorphous carbonized layer formed under the effect of high-dose ion implantation, a modified hardened layer formed under the effect of dry etching of an oxide film or a polysilicon film using a chlorine-based or fluorine-based gas, and the like can be mentioned. Photoresists include a positive type, where a region that is not sensitive to exposure remains, and a negative type, where a region that is sensitive to exposure remains. In the present invention, either type may be the object to be removed. Specific examples of organic materials to form a photoresist include, but are not limited to, a cresol novolac polymer that forms a g/i-ray resist (novolac resin), polyvinyl phenol that forms a KrF resist (PVP resin), and polymethyl methacrylate that forms an ArF resist (PMMA resin). The pattern of the patterned wafer substrate may be a pattern to serve as a circuit pattern, or may also be a pattern formed to perform ion implantation, plasma irradiation, or the like treatment on the wafer substrate. The width or pitch of the pattern is not particularly limited and may be 10 nm to 1 μm, for example.

The carbon dioxide dissolved water containing ozone-containing microbubbles used to remove a photoresist having a hardened modified layer, which is difficult to remove, formed on at least part of a top portion may be produced, for example, from water containing dissolved carbon dioxide and ozone using a known microbubble generator that employs a two-phase flow swirling method or a pressurized dissolution method. In the case where a two-phase flow swirling method is employed, a vortex flow having a radius of 10 cm or less is forcibly caused using a rotator or the like, and an ozone-containing gas-liquid mixture is struck against an obstacle, such as a wall surface, or against a fluid having a different relative velocity, whereby an ozone-containing gas body obtained in the vortex flow is dispersed under the process of distraction of the vortex. As a result, ozone-containing microbubbles desired can be generated in a large amount. In addition, in the case where a pressurized dissolution method is employed, an ozone-containing gas is dissolved in water at a high pressure of 2 atm or more and then depressurizing to the atmospheric pressure. As a result, ozone-containing bubbles can be generated from an ozone-containing dissolved gas under supersaturated conditions. In this case, at the pressure reduction region, a large number of vortexes having a radius of 1 mm or less are generated utilizing the water flow and an obstacle, and a large number of gas-phase nuclei (bubble nuclei) are formed due to the oscillation of water molecules in the central region of the vortex flow. At the same time, following the supersaturated conditions, the ozone-containing gas body in water is diffused toward these bubble nuclei resulting in the growth of the bubble nuclei. As a result, ozone-containing microbubbles desired can be generated in a large amount. Incidentally, bubbles generated by these methods are microbubbles having a particle size of 50 μm or less. The particle size has a peak at 10 to 15 μm as measured with a laser-light-blocking liquid particle counter (e.g., LiQuilaz-E20 manufactured by SPM Co., etc.), and the number of microbubbles in the peak region is 1000/mL or more (see JP-A-2000-51107, JP-A-2003-265938, etc., if necessary). “Ozone-containing microbubbles” means microbubbles containing at least ozone as a component of the interior gases, and may be microbubbles containing only ozone inside, or may also be microbubbles containing, in addition to ozone, gases other than ozone, such as carbon dioxide, oxygen, and nitrogen inside.

As water to dissolve carbon dioxide, ultrapure water widely used in a semiconductor manufacturing site may be used. Ultrapure water has, for example, an electrical conductivity of 0.061 μS/cm or less and a pH of 7. With respect to the amount of carbon dioxide dissolved in water, it is preferable that dissolution is performed such that the carbon dioxide concentration in water containing dissolved carbon dioxide (this carbon dioxide concentration is equivalent to the carbon dioxide concentration in a carbon dioxide dissolved water containing ozone-containing microbubbles eventually prepared) will be 0.05 ppm or more, more preferably 0.1 ppm or more, and most preferably 0.3 ppm or more. The upper limit of the carbon dioxide concentration is preferably 30 ppm, more preferably 10 ppm, and most preferably 5 ppm. When the amount of carbon dioxide dissolved in water is adjusted like this, the pH of the resulting water containing dissolved carbon dioxide is 5.0 to 6.0, that is, slightly acidic. By generating ozone-containing microbubbles in such a slightly acidic water, a carbon dioxide dissolved water containing ozone-containing microbubbles, which is capable of removing even a photoresist having a hardened modified layer, which is difficult to remove, formed on at least part of a top portion within a short period of time, can be prepared. Incidentally, the method for dissolving carbon dioxide in water is not particularly limited and may be a method in which a carbon dioxide gas is supplied to water through a hollow fiber gas permeation membrane, for example.

Incidentally, the method for producing a carbon dioxide dissolved water containing ozone-containing microbubbles is not limited to the above method in which ozone-containing microbubbles are generated in water containing dissolved carbon dioxide, and may also be a method in which the dissolution of carbon dioxide in water and the generation of ozone-containing microbubbles are simultaneously performed, for example.

The method for bringing a patterned wafer substrate, on which a photoresist having a hardened modified layer, which is difficult to remove, formed on at least part of a top portion is present, into contact with the carbon dioxide dissolved water containing ozone-containing microbubbles is not particularly limited. For example, such contact may be made by immersing a wafer substrate in a carbon dioxide dissolved water containing ozone-containing microbubbles, or pouring a carbon dioxide dissolved water containing ozone-containing microbubbles over a wafer substrate. In the case where a wafer substrate is immersed in a carbon dioxide dissolved water containing ozone-containing microbubbles, it is preferable that the wafer substrate is placed in flowing water, or that a carbon dioxide dissolved water containing ozone-containing microbubbles is sprayed over the wafer substrate in water. The method for pouring a carbon dioxide dissolved water containing ozone-containing microbubbles over a wafer substrate may be a free-flowing water method, a spray method, a shower method, or the like. Cleaning may be performed in a batch process, but is preferably performed in a single wafer process. This is because, as a result, self-contamination of the wafer substrate in the course of removing the photoresist having a hardened modified layer, which is difficult to remove, formed on at least part of a top portion can be avoided (see WO 2009/099138, if necessary).

It is preferable that the step of removing a photoresist having a hardened modified layer, which is difficult to remove, formed on at least part of a top portion using a carbon dioxide dissolved water containing ozone-containing microbubbles is performed with heating. This is because, as a result, the removal effect can be improved. The method for heating is not particularly limited. According to an easy method, the carbon dioxide dissolved water containing ozone-containing microbubbles is heated. In this case, it is preferable that the carbon dioxide dissolved water containing ozone-containing microbubbles is heated to 30° C. or more, more preferably 40° C. or more, and most preferably 45° C. or more. The upper limit of heating is preferably 80° C., more preferably 70° C., and most preferably 65° C. When heating is performed more than necessary, the hardened modified layer formed on at least part of a top portion of the photoresist may be further deteriorated, or another hardened modified layer may be formed.

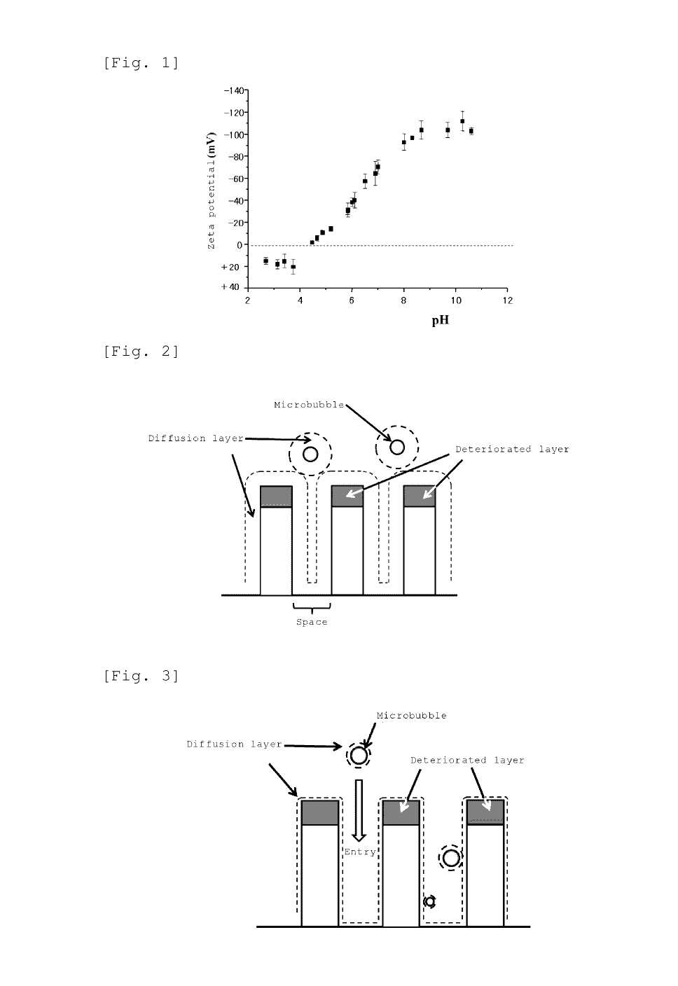

The reasons why a photoresist having a hardened modified layer, which is difficult to remove, formed on at least part of a top portion can be effectively removed by a carbon dioxide dissolved water containing ozone-containing microbubbles are mainly the following two points: even when a photoresist has a hardened modified layer, which is difficult to remove, formed on a top portion, there is an original, flexible photoresist that has not been hardened or deteriorated underneath; and ozone-containing microbubbles contained in the carbon dioxide dissolved water enter the grooves and holes of the pattern of the patterned wafer substrate, whereby the ozone-containing microbubbles act, from the side, on the flexible photoresist underlying the hardened modified layer. The dissolution of carbon dioxide in water containing ozone-containing microbubbles makes it easy for the ozone-containing microbubbles to enter the grooves and holes of a pattern. Microbubbles having a particle size of 50 μm or less, not only ozone-containing microbubbles, have the property of decreasing in size in water. Therefore, basically, they can enter any place no matter how small it is (accordingly, little or no disadvantage is caused by the grooves and holes of a pattern being small). However, microbubbles have gas-liquid interfaces, and such a gas-liquid interface is charged. Therefore, a microbubble is accompanied by a diffusion layer of ions having the opposite sign (counter ions) in the surrounding water of the microbubble. Although the gas-liquid interface of a microbubble immediately after generation is not charged, within an extremely short period of time, ions are redistributed at the gas-liquid interface and its vicinity, whereby the interface is charged. Such charges include H⁺ and OH resulting from the dissociation of a water molecule. These ions are likely to be accumulated at the gas-liquid interface of a microbubble in association with the hydrogen bond network of water molecules, and OH⁻ is particularly prone to such accumulation. Accordingly, gas-liquid interfaces are negatively charged. When the gas-liquid interface of a microbubble is negatively charged, H⁺ is accumulated therearound due to static electricity. Particularly in ultrapure water, because the ionic strength is low, and the pH is neutral, the gas-liquid interface of a microbubble is strongly negatively charged (about −70 mV as zeta potential; see FIG. 1), and H⁺ is widely dispersed therearound. Meanwhile, a photoresist, which is the object to be removed, also has hydrophobic properties, and thus its ion dispersibility is similar to that of microbubbles. As a result, an overlap is caused between the diffusion layer that accompanies an ozone-containing microbubble and the diffusion layer that accompanies a photoresist, and repulsion is generated, making it difficult for ozone-containing microbubbles to enter the grooves and holes of a pattern (see FIG. 2). Therefore, ozone-containing microbubbles can only act on the photoresist from above. However, also above the photoresist, there is repulsion between the photoresist and microbubbles. In addition, a hardened modified layer which is difficult to remove is present on a top portion of the photoresist. The present inventors have found that this is the reason why the removal of a photoresist takes a long period of time according to the method described in WO 2009/099138. In view of the above points, in order for ozone-containing microbubbles to enter the grooves and holes of a pattern and act on a flexible photoresist underlying a hardened modified layer from the side, it is important to reduce the overlap between the diffusion layer that accompanies an ozone-containing microbubble and the diffusion layer that accompanies a photoresist so as to reduce repulsion. The solution to this technical problem is carbon dioxide dissolved in water containing ozone-containing microbubbles. Water containing dissolved carbon dioxide is acidic, and thus reduces the negative charges at the interfaces of ozone-containing microbubbles and the interface of the photoresist. At the same time, it increases the ionic strength, and thus reduces the overlap between the diffusion layer that accompanies an ozone-containing microbubble and the diffusion layer that accompanies a photoresist, thereby reducing repulsion. As a result, the entry of ozone-containing microbubbles into the grooves and holes of a pattern is facilitated (see FIG. 3). When ozone-containing microbubbles enter the grooves and holes of a pattern, active species including hydroxyl radicals decompose or solubilize the flexible photoresist from the side. In addition, due to the self-pressurization effect, the pressure inside a microbubble increases in inverse proportion to the bubble diameter. Thus, according to Henry's law, the ozone-containing microbubbles that have entered the grooves and holes of a pattern supply ozone inside the bubbles to the flexible photoresist underlying the hardened modified layer. Hence, as a result of the entry of ozone, the flexible photoresist expands in volume, while also as a result of the entry of carbon dioxide dissolved in water, the photoresist expands in volume. Such volume expansion of a flexible photoresist is caused by the dispersion, accompanied by diffusion, of ozone or carbon dioxide into the photoresist. Accordingly, their distribution inside the photoresist is not uniform, and the distribution varies in density from side to center. As a result, the degree of volume expansion of the flexible photoresist varies from place to place. This causes stress on the hardened modified layer on a top portion of the photoresist, promoting the physical destruction of the hardened modified layer. Once the physical destruction of the hardened modified layer starts, ozone-containing microbubbles enter the space resulting from the destruction, and active species including hydroxyl radicals decompose or solubilize the hardened modified layer that has started collapsing. As a result of such phenomena in combination, the photoresist having a hardened modified layer, which is difficult to remove, formed on at least part of a top portion is decomposed, dissolved in water, and discharged out of the system, or, even if not dissolved, separated from the wafer substrate and discharged out of the system together with water; accordingly, the photoresist is effectively removed. The amount of carbon dioxide dissolved in water described above has been set to maximize the above effect of carbon dioxide dissolved in water. When the amount of carbon dioxide dissolved in water is too small, the above effect may not be obtained. Meanwhile, when the amount of carbon dioxide dissolved in water is too large, it may happen that the pH is too small, causing the dissipation of negative charges at the interfaces of ozone-containing microbubbles and the interface of the photoresist, and, as a result, the ozone-containing microbubbles directly hit the photoresist, and are physically collapsed, making it impossible to obtain the above effect. In addition, it may happen that the collapse of microbubbles generates a jet, which is a group of smaller bubbles, and an intense impact pressure is applied to the formed circuit pattern at a speed of more than 100 m/sec, thereby adversely affecting to the pattern (in view of these points, the lower limit of pH is preferably 4.5). Heating performed at the time of removing a photoresist having a hardened modified layer, which is difficult to remove, formed on at least part of a top portion using a carbon dioxide dissolved water containing ozone-containing microbubbles enhances the flexibility of the photoresist underlying the hardened modified layer. As a result, the photoresist further expands in volume upon the entry of ozone or carbon dioxide, and, at the same time, decomposition or solubilization caused by active species including hydroxyl radicals is further promoted. The overlap between the diffusion layer that accompanies an ozone-containing microbubble and the diffusion layer that accompanies a photoresist is increased by heating. However, the acidification caused by carbon dioxide dissolved in water sufficiently offsets such an increase in the overlap between the diffusion layers.

The phenomenon that the flexible photoresist underlying the hardened modified layer expands in volume upon the entry of ozone or carbon dioxide is a novel finding by the present inventors. This phenomenon is caused by the self-pressurization effect of microbubbles, the control of charges around bubbles, the following control of the contact between the microbubbles and the photoresist, and the like. The self-pressurization effect is based on the surface tension that acts on the gas-liquid interfaces surrounding ozone-containing microbubbles, and is characterized in that the smaller the bubbles are, the more they are pressurized. The value can be predicted by the Young-Laplace equation, and is represented by the equation: P=P1+2 σ/r. Here, P is the gas pressure inside a bubble, P1 is the surrounding environmental pressure, σ is the surface tension, and r is the radius of the bubble. The control of charges around bubbles and the following control of the contact between the microbubbles and the photoresist are caused by carbon dioxide dissolved in water containing ozone-containing microbubbles as described above. Use of carbon dioxide makes it easy to turn water containing ozone-containing microbubbles weakly acidic. At the same time, unlike the case of using an acid, there is no need to care about waste liquid disposal. In addition, little or no adverse effect is caused by remaining water on the wafer substrate.

Incidentally, for the purpose of compensating for or enhancing the removing effect of the carbon dioxide dissolved water containing ozone-containing microbubbles on a photoresist having a hardened modified layer, which is difficult to remove, formed on at least part of a top portion, it is also possible that a wafer substrate, on which a photoresist having a hardened modified layer formed on at least part of a top portion is present, may be subjected to at least one treatment selected from a treatment of roughening a surface of the hardened modified layer and a treatment of forming a scratch and/or a crack on a surface of the hardened modified layer before and/or with the step of removing the photoresist using a carbon dioxide dissolved water containing ozone-containing microbubbles. As a result of such surface treatments, stress caused by the action of ozone-containing microbubbles, which promotes the physical destruction, or decomposition or solubilization of the hardened modified layer present on a top portion of the photoresist, can be imparted from above or side of the photoresist. Such surface treatments can be performed by known brush scrubbing, for example, by pressing and rotating a Teflon (Registered Trademark) brush against the surface of a crust.

In addition, the step of removing a photoresist having a hardened modified layer, which is difficult to remove, formed on at least part of a top portion using a carbon dioxide dissolved water containing ozone-containing microbubbles may be combined with known steps, such as a step of removing a photoresist using a liquid chemical containing sulfuric acid or hydrogen peroxide as a main component.

According to the method for manufacturing a semiconductor of the present invention, as long as the step of removing a photoresist having a hardened modified layer, which is difficult to remove, formed on at least part of a top portion using a carbon dioxide dissolved water containing ozone-containing microbubbles is included in a wafer processing step, other steps in the wafer processing step may be known steps. In addition, steps for manufacturing a semiconductor other than the wafer processing step, such as a circuit design step, a mask manufacturing step, a wafer manufacturing step, an assembly step, an inspection step, and a waste processing step, may also be known steps.

### EXAMPLES

Hereinafter, the present invention will be described in detail with reference to the examples. However, the present invention should not be construed as being limited to the following descriptions.

### Example 1

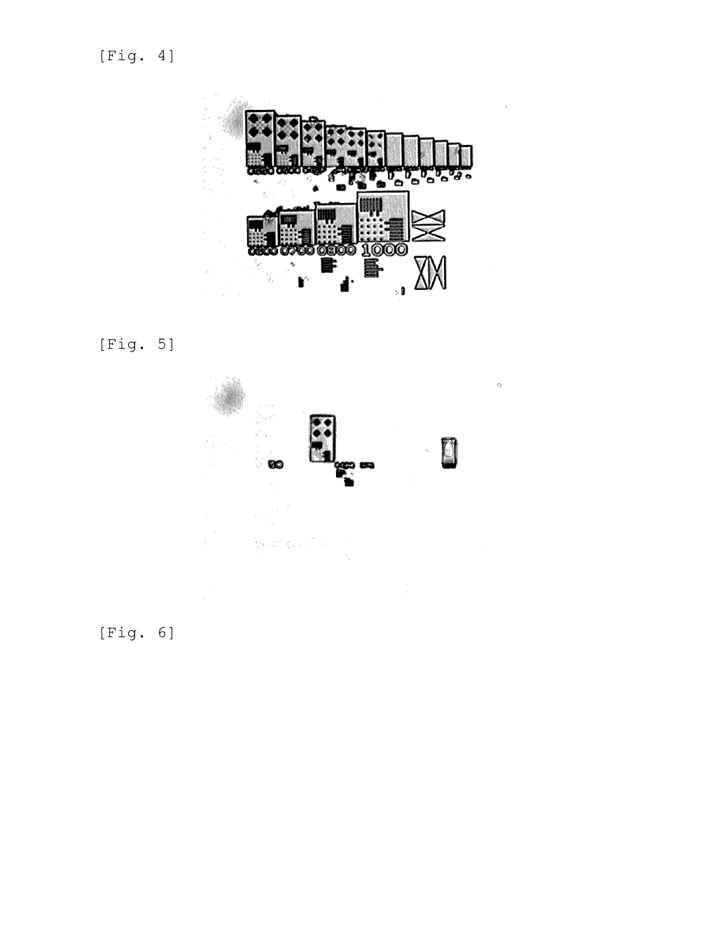

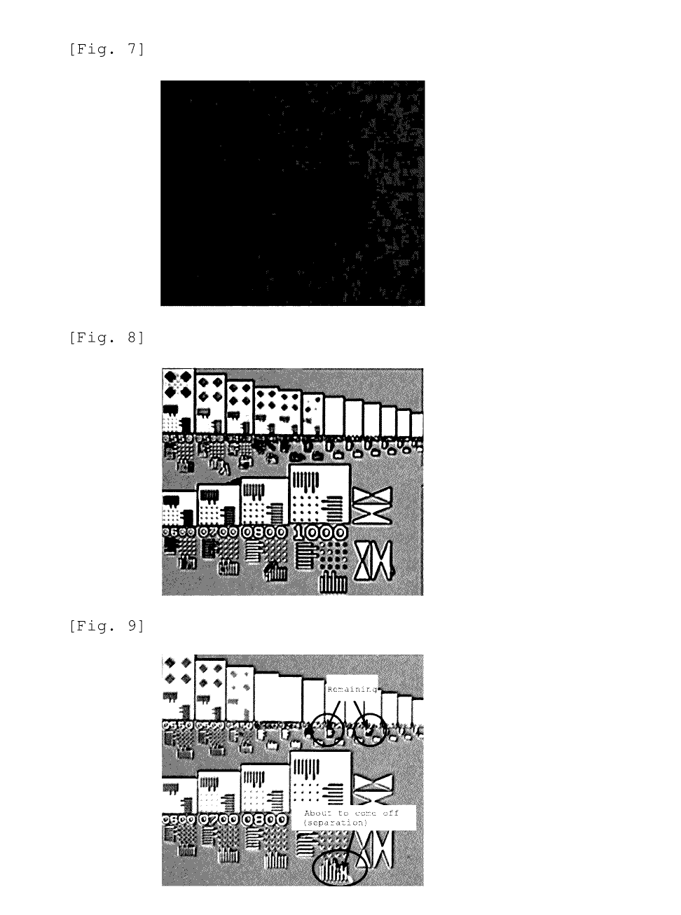

(1) Under room temperature conditions, 4000 mL of ultrapure water was placed in a 5000 mL beaker, and a carbon dioxide gas was released into ultrapure water in the beaker. While dissolving carbon dioxide, ultrapure water in the beaker was drawn into a known microbubble generator (see JP-A-2003-265938, if necessary), and, at the same time, an ozone gas was supplied to the generator at a concentration of about 350 g/Nm³. As a result, ozone-containing microbubbles (ozone microbubbles) having a particle size of 50 μm or less were continuously generated in water. The particle size had a peak at 10 to 15 μm as measured with a laser-light-blocking liquid particle counter (LiQuilaz-E20 manufactured by SPM Co.), and the number of microbubbles in the peak region was 1000/mL or more. Incidentally, the yield of the carbon dioxide dissolved water containing ozone microbubbles was set at about 2 L/min. The water level in the beaker was maintained by continuously supplying ultrapure water. The carbon dioxide dissolved water containing ozone microbubbles had a carbon dioxide concentration of about 0.5 ppm, a pH of about 5.7, and an electrical conductivity of about 1 μS/cm.
(2) In order to form a resist pattern having a size of L/S (Line & Space)=0.50 μm/0.50 μm on a wafer substrate, an 8-inch diameter silicon wafer having a photoresist made of a novolac resin (TDMR-AR87LB manufactured by Tokyo Ohka Kogyo Co., Ltd.) applied to its surface to a thickness of 1300 nm was exposed using an i-ray stepper (FPA-3000i manufactured by Canon Inc.), followed by development using an alkaline developing solution (NMD-W manufactured by Tokyo Ohka Kogyo Co., Ltd.). Next, a heat treatment at 100° C. (postbake) was performed to sinter the resist, and then phosphorus (P) ions were implanted at a high dose (1×10¹⁵ ions/cm², 60 KeV). As a result of this treatment, a crust composed of an amorphous carbonized layer was formed on the surface of the photoresist on the wafer substrate (based on the image analysis of a cross-section of the photoresist using a scanning electron microscope).
(3) The wafer substrate produced in (2), on which the photoresist having a crust formed on its surface was present, was placed on a spin stage, and the spin stage was rotated at a speed of 200 rpm. At the same time, the carbon dioxide dissolved water containing ozone microbubbles generated in (1) was discharged from a discharge nozzle set about 5 cm above the center of the substrate surface, and continuously poured over the wafer substrate placed on the spin stage. The carbon dioxide dissolved water containing ozone microbubbles to be discharged from the discharge nozzle was heated by a heating coil arranged in front of the nozzle, and discharged from the discharge nozzle at a water temperature of about 50° C.
(4) FIG. 4 shows a microphotograph of the wafer substrate before pouring the carbon dioxide dissolved water containing ozone microbubbles, FIG. 5 shows a microphotograph of the same portion after 3 minutes from the start of the pouring of the carbon dioxide dissolved water containing ozone microbubbles, and FIG. 6 shows a microphotograph of the same portion after 5 minutes. As is clear from FIGS. 4 to 6, the removal of the photoresist having a crust formed on its surface from the wafer substrate proceeded in a mode different from the mode in which the removal proceeds due to the dissolution of a photoresist, and the photoresist was entirely removed after 5 minutes from the start of the pouring of the carbon dioxide dissolved water containing ozone microbubbles. FIG. 7 is a microphotograph of a different portion after 2 minutes from the start of the pouring of the carbon dioxide dissolved water containing ozone microbubbles. The photo captures the moment when the photoresist was about to be separated from the wafer substrate. This means that ozone microbubbles contained in the carbon dioxide dissolved water entered the grooves of the pattern of the photoresist, whereby the ozone microbubbles acted on the flexible photoresist underlying the crust from the side, making it impossible to maintain the adhesion of the photoresist to the wafer substrate any longer.

### Example 2

A carbon dioxide dissolved water containing ozone microbubbles at a water temperature of 22° C. was poured over a wafer substrate in the same manner as in Example 1, except that the carbon dioxide dissolved water containing ozone microbubbles discharged from the discharge nozzle was not heated. As a result, even after the lapse of 30 minutes from the start of the pouring of the carbon dioxide dissolved water containing ozone microbubbles, the photoresist having a crust formed on its surface was not entirely removed. However, about 60 to 70% was removed, and, as a result of further continuing the pouring of the carbon dioxide dissolved water containing ozone microbubbles, the photoresist was entirely removed.

### Example 3

A carbon dioxide dissolved water containing ozone microbubbles was poured over a wafer substrate in the same manner as in Example 1, except that the carbon dioxide dissolved water containing ozone microbubbles was poured after brush scrubbing the wafer substrate. As a result, by previously brush scrubbing the wafer substrate over which a carbon dioxide dissolved water containing ozone microbubbles was to be poured, it was possible to reduce the time taken to remove the photoresist having a crust formed on its surface. Incidentally, the wafer substrate was brush scrubbed for 60 seconds as follows. While pouring a carbon dioxide dissolved water containing ozone microbubbles over the wafer substrate, a 3-cm diameter cylindrical Teflon (Registered Trademark) brush was brought into contact with the surface of the substrate using a vertical shaft at a pushing pressure of 1 kg/cm², and moved while being rotated at 300 rpm.

### Example 4

A carbon dioxide dissolved water containing ozone microbubbles was poured over a wafer substrate in the same manner as in Example 1, except that in place of the photoresist made of a novolac resin, a photoresist made of a PMMA resin (TArF-P6111 manufactured by Tokyo Ohka Kogyo Co., Ltd.) was applied to the surface of a silicon wafer, followed by exposure and development by predetermined methods. As a result, after 10 minutes from the start of the pouring of the carbon dioxide dissolved water containing ozone microbubbles, the photoresist having a crust formed on its surface was entirely removed.

### Example 5

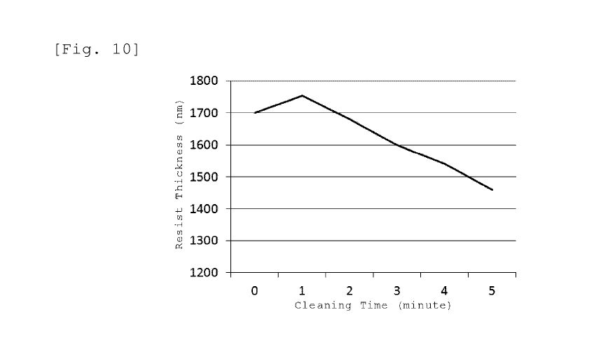

The wafer substrate developed in Example 1 (2) was subjected to a treatment equivalent to dry etching of an oxide film or a polysilicon film using a mixed gas of C₅F₈/Ar/O₂ under the following conditions; pressure: 20 mT, RF power: Top/Bot=2000 W/1600 W. Subsequently, a carbon dioxide dissolved water containing ozone microbubbles was poured over the wafer substrate in the same manner as in Example 1. FIG. 8 shows a microphotograph of the wafer substrate before pouring the carbon dioxide dissolved water containing ozone microbubbles, and FIG. 9 shows a microphotograph of the same portion after 3 minutes from the start of the pouring of the carbon dioxide dissolved water containing ozone microbubbles. As is clear from FIGS. 8 and 9, 90% or more of the photoresist having a hardened modified layer formed on its surface was removed from the wafer substrate after 3 minutes from the start of the pouring of the carbon dioxide dissolved water containing ozone microbubbles. FIG. 9 also captures the moment when the photoresist was about to be separated from the wafer substrate. Thus, it was possible to confirm that ozone microbubbles contained in the carbon dioxide dissolved water entered the grooves of the pattern of the photoresist, whereby the ozone microbubbles acted on the flexible photoresist underlying the hardened modified layer from the side, making it impossible to maintain the adhesion of the photoresist to the wafer substrate any longer.

### Comparative Example 1

Ultrapure water containing dissolved carbon dioxide was poured over a wafer substrate in the same manner as in Example 1, except that ozone microbubbles were not generated by a microbubble generator. As a result, even after the lapse of 60 minutes from the start of the pouring of ultrapure water containing dissolved carbon dioxide, the photoresist having a crust formed on its surface was not removed at all. Further, even after further continuing the pouring of ultrapure water containing dissolved carbon dioxide, the photoresist was not removed at all.

### Comparative Example 2

Ultrapure water containing ozone microbubbles was poured over a wafer substrate in the same manner as in Example 1, except that a carbon dioxide gas was not released into ultrapure water in which ozone microbubbles were to be generated, and thus carbon dioxide was not dissolved. As a result, even after the lapse of 60 minutes from the start of the pouring of ultrapure water containing ozone microbubbles, the photoresist having a crust formed on its surface was not entirely removed. However, about 30 to 40% was removed, and, as a result of further continuing the pouring of ultrapure water containing ozone microbubbles, the photoresist was entirely removed.

### Reference Example 1

A carbon dioxide dissolved water containing ozone microbubbles generated in the same manner as in Example 1 (1), expect that an ozone gas was supplied to a microbubble generator at a concentration of about 30 g/Nm³, was poured over an 8-inch diameter silicon wafer having a photoresist made of a novolac resin (TDMR-AR87LB manufactured by Tokyo Ohka Kogyo Co., Ltd.) applied to its surface to a thickness of 1700 nm in the same manner as in Example 1 (3). After the start of the pouring of the carbon dioxide dissolved water containing ozone microbubbles, pouring was interrupted every minute, and the thickness of the photoresist was measured at nearly uniformly dispersed nine points using an optical thin film measurement device (Filmetrics F20 manufactured by Filmetrics, Inc.). The results are shown in FIG. 10 (the average of values measured at nine points). As is clear from FIG. 10, the thickness of the photoresist increased at the beginning of the pouring of the carbon dioxide dissolved water containing ozone microbubbles, but then gradually decreased. This phenomenon means the following: when the carbon dioxide dissolved water containing ozone microbubbles was poured over the flexible photoresist, the photoresist expanded in volume due to the entry of ozone inside a bubble of the ozone microbubbles or carbon dioxide dissolved in water, whereby the thickness increased. Subsequently, decomposition or solubilization of the photoresist by active species including hydroxyl radicals proceeded, whereby the thickness decreased.

### Application Example 1

Employing a step of removing a photoresist present on a patterned wafer substrate and having a crust formed on its surface in the same manner as in Example 1, a semiconductor was manufactured in accordance with a standard method for manufacturing a semiconductor.

### INDUSTRIAL APPLICABILITY

The present invention makes it possible to provide a method for manufacturing a semiconductor, including a step of removing a photoresist present on a patterned wafer substrate and having a hardened modified layer, which is difficult to remove, formed on at least part of a top portion easily and effectively under mild conditions, and a method for cleaning a wafer substrate, including the above step. In this respect, the present invention is industrially applicable.

1. A method for manufacturing a semiconductor, characterized by comprising a step of bringing a patterned wafer substrate, on which a photoresist having a hardened modified layer formed on at least part of a top portion is present, into contact with a carbon dioxide dissolved water containing ozone-containing microbubbles, thereby removing the photoresist.

2. The method for manufacturing a semiconductor according to claim 1, characterized in that the microbubbles have a particle size of 50 μm or less, the particle size has a peak at 10 to 15 μm as measured with a laser-light-blocking liquid particle counter, and the number of microbubbles in the peak region is 1000/mL or more.

3. The method for manufacturing a semiconductor according to claim 1, characterized in that the carbon dioxide dissolved water containing ozone-containing microbubbles is prepared by generating ozone-containing microbubbles in water containing dissolved carbon dioxide.

4. The method for manufacturing a semiconductor according to claim 1, characterized in that the carbon dioxide dissolved water containing ozone-containing microbubbles has a carbon dioxide concentration of 0.05 to 30 ppm.

5. The method for manufacturing a semiconductor according to claim 1, characterized in that the carbon dioxide dissolved water containing ozone-containing microbubbles has a pH of 4.5 to 6.0.

6. The method for manufacturing a semiconductor according to claim 1, characterized in that the step of removing the photoresist is performed with heating.

7. The method for manufacturing a semiconductor according to claim 6, characterized in that the heating is performed to 30 to 80° C.

8. The method for manufacturing a semiconductor according to claim 1, characterized in that, before and/or with the step of removing the photoresist, the patterned wafer substrate, on which a photoresist having a hardened modified layer formed on at least part of a top portion is present, is subjected to at least one treatment selected from a treatment of roughening a surface of the hardened modified layer and a treatment of forming a scratch and/or a crack on a surface of the hardened modified layer.

9. A method for cleaning a wafer substrate, characterized by comprising a step of bringing a patterned wafer substrate, on which a photoresist having a hardened modified layer formed on at least part of a top portion is present, into contact with a carbon dioxide dissolved water containing ozone-containing microbubbles, thereby removing the photoresist.
